(19) United States
(12) Patent Application Publication
(10) Pub. No.: US 2026/0056282 A1
(43) Pub. Date: Feb. 26, 2026

(54) DISPLAY PANEL ATTACHMENT ARRANGEMENTS FOR VEHICLES, AND METHODS OF DETERMINING THE POSITION OF A DISPLAY PANEL

(71) Applicant: Roadvert Limited, Glasgow (GB)

(72) Inventor: Lawrence CRAIG, Glasgow (GB)

(73) Assignee: Roadvert Limited, Glasgow (GB)

(21) Appl. No.: 19/376,401

(22) Filed: Oct. 31, 2025

Related U.S. Application Data
(63) Continuation of application No. PCT/GB2024/051169, filed on May 3, 2024.

(30) Foreign Application Priority Data
May 3, 2023 (GB) 2306528.7

(51) Int. Cl. G01S 5/02; B60R 11/00; B60R 11/02; G06Q 30/0251; G09F 21/04; H05K 5/02

(52) U.S. Cl. CPC G01S 5/0295; B60R 11/0235; G01S 5/0226; G06Q 30/0265; G09F 21/048; H05K 5/0204; B60R 2011/004; B60R 2011/0071; B60R 2011/0077

(57) ABSTRACT

A method by which the position of a display panel or of a vehicle can be determined by broadcasting a message from a beacon associated with the display panel or the vehicle, receiving the broadcast message at a consumer device, determining the position of the consumer device when the message is received, and taking that position to be the position of the display panel or of the vehicle. If this is done with multiple messages and/or multiple consumer devices the position of the display panel or of the vehicle can be determined as a function of time.

### CROSS REFERENCE TO RELATED APPLICATIONS

This application is a continuation of International Patent Application No. PCT/GB2024/051169, filed May 3, 2024, which claims priority to GB Patent No. 2306528.7, filed May 3, 2023, the contents of each of which are incorporated by reference herein.

### FIELD OF THE INVENTION

The present invention relates to display panels for vehicles such as advertising panels for use on external surfaces of public transport and the like. More specifically, the present invention concerns improvements to display panels which may be removably fastened to a vehicle, how the position of a display panel is determined, and how the level of exposure of the display panel to the public is reliably estimated and/or verified. In particular embodiments of the invention there are provided display panel attachment arrangements for vehicles which permit reliable and removeable attachment of display panels and retention of associated beacons which can communicate with members of the public, and in other embodiments of the invention there are provided means and methods for determining the position of a display panel and identifying the extent of exposure of the display panel to the public.

### BACKGROUND

There are a number of vehicle side advertising solutions that permit the attachment of display panels to promote and advertise brands. Sometimes it is the owner of the vehicle whose brand is being advertised; other times the side of the vehicle is effectively leased out as advertising space and it is another party's brand which is being advertised.

Regardless of the reasons, it is decidedly beneficial if these can be applied and removed easily, for example when replacing, repairing or even rebranding.

The most basic of these systems involves the direct application of printed adhesive backed vinyl to the sides of trucks. This is the simplest approach and by use of pressure sensitive vinyl graphics the application of such panels can be made relatively easy. However, this is an expensive approach and removal can be difficult and risks damage to the vehicle substrate.

Systems such as Agripa's AgripaFrame™ system instead apply a frame around the periphery of a vehicle substrate. The frame provides rails top and bottom which receive corresponding keder edge strips that are stitched along the top and bottom edges of a printed mesh sheet (the display panel)—the keder edge strips forming a bead that is fed into and along the rails when installing a new display panel. EPIC Media Group's KWIK ZIP™ system similarly employs a frame system but with a more complicated interlocking retaining arrangement which requires the use of specialist tools to install and remove.

Despite technological and commercial success of such display panel attachment arrangements it is always desirable to provide alternative attachment arrangements to facilitate new features, permit retro-fitting and also enable such display panels to be mounted on vehicles which have not previously been used for such purposes for one reason or another. It is also desirable to increase the functionality of display panel arrangements to improve the impact or delivery of a message which the display panel bears.

Accordingly, it is an object of at least one aspect of the present invention to provide an alternative to known display panel attachment arrangements. Also, it is an object of at least one aspect of the present invention to provide display panel attachment arrangements, known or otherwise, with increased functionality.

The applicant has also realised that in the relevant art there is no way of reliably identifying or quantifying the impact or delivery of the message which the display panel bears, e.g. how many people have seen the display panel.

Accordingly, it is an object of at least one aspect of the present invention to identify the extent to which a display panel has been exposed to the public.

To date there has also been no adequate solution to allow the cost-effective and non disruptive application of display panels to the shutter doors typically installed on trucks and some intermodal containers—or indeed shop fronts and garages. Such shutter doors will typically comprise 7 or 14 interlocking or hinged horizontal slats which run along vertical guide tracks as the shutter door is opened or closed. Typically, truck shutters will slide up and along the ceiling of the truck although it is also known for truck shutters to roll onto a drum—although such shutters typically have many more slats.

It is not possible to employ any of the above described framed or frameless display panel systems to such doors because of the curvature which the shutter undergoes when opening and closing and the increased distance between adjacent slats when so curved. This could result in stretching, tearing or other form of damage to the display panels; particularly as depending on the purpose of the truck the shutter door may be opened a few times a day (e.g. haulage) to a few tens of times a day (e.g. courier).

Presently, the only solution known to the Applicant is to apply individual adhesive display panel sections to individual shutter slats. However, this is a time-consuming process and, as noted above in relation to the use of printed adhesive-backed vinyl on the sides of trucks, risks damage to the shutter door on removal.

Accordingly, it is an object of at least one aspect of the present invention to provide a display panel attachment device for shutter doors that obviates and mitigates one or more disadvantages of the prior art and enables the use of larger single piece display panels on such substrates.

Further aims and objects of the invention will become apparent from reading the following description.

### SUMMARY

According to a first aspect of the invention, there is provided a display panel attachment arrangement to attach a display panel to a vehicle, the display panel attachment arrangement comprising at least one rail to receive a corresponding at least one edge of the display panel, and at least one reclosable fastening to receive a corresponding at least one reclosable fastening of the display panel, the at least one rail and the at least one reclosable fastening arranged on the vehicle to define a shape corresponding to the shape of the display panel.

Preferably, the at least one rail is arranged along a top edge of the display panel attachment arrangement. Preferably, the at least one rail is continuous, but optionally the at least one rail is discontinuous and may comprise at least one gap defining at least first and second rail portions.

Optionally, the display panel attachment arrangement comprises a plurality of rails, each of which may be arranged horizontally to receive corresponding horizontal edges of the display panel, in which case the at least one reclosable fastening may be arranged vertically to receive a corresponding at least one vertical edge of the display panel.

Optionally, the display panel attachment arrangement defines a rectangular shape. Alternatively, the display panel attachment may define any other geometric shape, including but not limited to a T-shape.

The at least one rail and/or the at least one reclosable fastening may be attached to the vehicle using any suitable attachment means, including but not limited to adhesives, reclosable fastenings, ultrasonic welding and/or rivets.

Preferably, the at least one rail comprises a channel configured to receive a keder strip disposed along an edge of the display panel and a flange for attachment to the vehicle configured for location behind the display panel when in use.

Preferably, the display panel attachment arrangement further comprises at least one outlet to enable fluid to escape from behind the display panel in use. Preferably, the at least one outlet is provided in a vertical portion of the attachment arrangement, optionally by at least one gap provided in at least one reclosable fastening. Alternatively, or additionally, the at least one outlet may be provided in a horizontal portion of the attachment arrangement.

Embodiments of the first aspect of the invention may comprise features corresponding to the preferred or optional features of any other aspect of the invention or vice versa.

According to a second aspect of the invention there is provided a method of attaching a display panel to a vehicle, comprising providing the vehicle with a display panel attachment arrangement according to the first aspect.

Preferably, the method further comprises receiving at least one edge of the display panel in at least one rail of the display panel attachment arrangement. Optionally, the method comprises receiving the at least one edge of the display panel in the at least one rail via a gap in the at least one rail.

Preferably, the method further comprises receiving at least one reclosable fastening of the display panel on at least one reclosable fastening of the display panel attachment arrangement.

Providing the vehicle with the display panel attachment arrangement may comprise attaching the at least one rail and the at least one reclosable fastening to the vehicle. The at least one rail and/or the at least one reclosable fastening may be attached to the vehicle using any suitable attachment means, including but not limited to adhesives, reclosable fastenings, ultrasonic welding and/or rivets.

Optionally, the method comprises applying strips of reclosable fastenings to the vehicle in a discontinuous manner to provide at least one gap which functions as a fluid outlet of the display panel attachment arrangement.

Embodiments of the second aspect of the invention may comprise features corresponding to the preferred or optional features of any other aspect of the invention or vice versa.

According to a third aspect of the invention there is provided a display panel attachment arrangement to attach a display panel to a vehicle, the display panel attachment arrangement comprising a beacon arranged on or within the display panel attachment arrangement and configured to transmit or broadcast one or more messages to one or more electronic devices in the vicinity of the vehicle.

The display panel attachment arrangement may be a display panel attachment arrangement according to the first aspect, and/or a display panel attachment arrangement provided on a vehicle in accordance with the second aspect.

Optionally, the beacon is integral to the display panel attachment arrangement. The beacon may be located on a horizontal portion of the display panel attachment arrangement, or it may be located on a vertical portion of the display panel attachment arrangement.

Alternatively, the beacon is located within an area bounded by the at least one rail and at least one reclosable fastening of the display panel attachment arrangement.

Most preferably, the beacon is covered when the display panel is in place. Optionally, the display panel assists in retaining the beacon.

Preferably, the display panel attachment arrangement is configured to attach a display panel to the side of a vehicle. Alternatively, the display panel attachment arrangement is configured to attach a display panel to the rear door of a vehicle. Such a display panel attachment arrangement may comprise reclosable fastenings or a rail to fixedly attach the display panel to the door along a top edge and a resilient, extendible, retractable or flexible tether to attach the display panel to the door along a bottom edge.

Optionally, the beacon is further configured to track the position of the vehicle.

Embodiments of the third aspect of the invention may comprise features corresponding to the preferred or optional features of any other aspect of the invention or vice versa.

According to a fourth aspect of the invention there is provided a method of transmitting or broadcasting one or more messages to one or more electronic devices in the vicinity of a vehicle, the method optionally comprising providing the vehicle with a display panel attachment arrangement according to the third aspect.

Preferably, the method comprises transmitting or broadcasting one or more messages which relate to the subject matter presented on a display panel attached to the vehicle by the display panel attachment arrangement.

Optionally, the method comprises transmitting or broadcasting one or more messages which relate to or are dependent upon the position of the vehicle.

Embodiments of the fourth aspect of the invention may comprise features corresponding to the preferred or optional features of any other aspect of the invention or vice versa.

According to a fifth aspect of the invention, there is provided a method of determining the extent to which a display panel has been exposed to the public, the method comprising tracking the position of a vehicle to which the display panel is attached to generate positional data, and correlating the positional data with one or more databases.

Preferably, the method comprises correlating the positional data with the one or more databases to determine how many people can be expected to have seen the vehicle. Optionally, correlating the positional data with one or more databases is performed in real-time.

Optionally, the method further comprises transmitting or broadcasting one or more messages to one or more electronic devices in the vicinity of the vehicle based on the positional data. Optionally, the method comprises providing the vehicle with a display panel attachment arrangement according to the third aspect.

Embodiments of the fifth aspect of the invention may comprise features corresponding to the preferred or optional features of any other aspect of the invention or vice versa.

According to a sixth aspect of the invention, there is provided a vehicle, the vehicle comprising at least one display panel attachment arrangement according to the first or third aspect of the invention.

The vehicle may be provided with at least one display panel attached to the at least one display panel attachment arrangement.

Optionally, the vehicle further comprises a positioning device arranged on or in the vehicle and configured to track the position of the vehicle for the purposes of determining the extent to which a display panel attached to the vehicle has been exposed to the public in accordance with the fifth aspect.

Embodiments of the sixth aspect of the invention may comprise features corresponding to the preferred or optional features of any other aspect of the invention or vice versa.

According to a seventh aspect of the invention, there is provided a display panel attachment device for a shutter door, the display panel attachment device comprising at least one tether, the tether connectable at a first end to an edge of the display panel, attachable at a second end to the shutter door, and extendible to prevent stretching of the display panel as the shutter door is opened or closed.

As the shutter door is opened or closed, the extendible tether allows the display panel to remain attached to the shutter door without stretching as the effective length of the shutter door increases due to its curvature. In other words, the increase in tension that would otherwise be applied to the display panel and hence risk damage thereto is instead taken up by extension of the tether.

Most preferably, the tether is resilient.

Resilience permits tension on the display panel to be maintained when the shutter door is closed, particularly when the shutter door is closed from an open position during which the tether was extended.

Preferably, the resilient tether comprises one or more springs.

Alternatively, the resilient tether may comprise an elasticated cord or similar extendable ligament.

Further alternatively, the tether is retractable.

Optionally, the retractable tether comprises a tensioned roller. The tensioned roller may be connected to the display panel using one or more lines or sheets disposed on the roller. Alternatively, the display panel may be connected directly to the roller along an edge of the display panel, and a portion of the display panel retractable on the roller.

Preferably, the tether is attachable to the shutter door via a support member to which the tether is connected at the second end, the support member configured for attachment to the shutter door.

Preferably, the support member comprises one or more fastenings corresponding with one or more fastenings disposed on the shutter door. Preferably, the one or more fastenings comprise reclosable fastenings. Examples of such reclosable fastenings include Dual Lock™ strips and hook-and-loop fastenings.

Alternatively, the support member is configured for attachment to the shutter door by providing at least one adhesive portion on a contacting surface of the support member.

Preferably, the tether is connectable to a lower edge of the display panel. Alternatively, or additionally, the tether is connectable to an upper edge of the display panel.

Preferably, the display panel attachment device further comprises a rod for disposal along, proximal or within an edge of the display panel, the tether connectable to the rod.

Embodiments of the seventh aspect of the invention may comprise features corresponding to the preferred or optional features of any other aspect of the invention or vice versa.

According to an eighth aspect of the invention, there is provided a display panel assembly comprising a display panel and a first display panel attachment device according to the first aspect connected to the display panel.

Optionally, the display panel assembly comprises a second display panel attachment device according to the first aspect connected to the display panel at an end opposite the first display panel attachment device.

Alternatively, the display panel is adapted for direct attachment to the shutter door at an end opposite the first display panel attachment device. Preferably, the display panel comprises one or more fastenings corresponding with one or more fastenings disposed on the shutter door. Preferably, the one or more fastenings comprise reclosable fastenings such as Dual Lock™ strips or hook-and-loop fastenings. Alternatively, the display panel comprises at least one adhesive portion.

Preferably, the display panel assembly further comprises one or more clips to supplement or reinforce the direct attachment of the display panel to the shutter door.

Preferably, the display panel comprises a substantially non-permeable flexible sheet.

Alternatively, the display panel comprises a flexible mesh sheet.

Embodiments of the eighth aspect of the invention may comprise features corresponding to the preferred or optional features of any other aspect of the invention or vice versa.

According to a ninth aspect of the invention there is provided a shutter door display comprising a shutter door and a display panel attached to the shutter door at one end by a display panel attachment device according to the seventh aspect.

Optionally, the display panel is attached to the shutter door at the opposite end by another display panel attachment device according to the first aspect. Alternatively, the display panel is attached directly to the shutter door at the opposite end.

Embodiments of the ninth aspect of the invention may comprise features corresponding to the preferred or optional features of any other aspect of the invention or vice versa.

According to a tenth aspect of the invention there is provided a truck comprising a shutter door display according to the ninth aspect.

Embodiments of the tenth aspect of the invention may comprise features corresponding to the preferred or optional features of any other aspect of the invention or vice versa.

According to an eleventh aspect of the invention there is provided a method of installing a display panel on a shutter door comprising:
attaching a first display panel attachment device according to the seventh aspect to the shutter door; and
attaching a first end of the display panel to the first display panel attachment device.

Optionally, the method further comprises attaching the second end of the display panel to the shutter door.

Optionally, attaching the second end of the display panel to the shutter door comprises attaching a second display panel attachment device according to the seventh aspect to the shutter door and attaching the second end of the display panel to the second display panel attachment device.

Alternatively, the second end of the display panel is directly attached to the shutter door.

Preferably, the method further comprises supplementing or reinforcing the direct attachment of the display panel to the shutter door using one or more clips.

Optionally, the method comprises attaching one or more strips of Dual Lock™ reclosable fastening material to one or more of the shutter door, the display panel, and/or one or more display panel attachment devices.

Embodiments of the eleventh aspect of the invention may comprise features corresponding to the preferred or optional features of any other aspect of the invention or vice versa.

It will be appreciated that the invention extends to constituent parts which are used in the seventh to eleventh aspects. Therefore according to a twelfth aspect of the invention, there is provided a kit of parts which, when assembled, forms a display panel attachment device for a shutter door, the kit of parts comprising at least one extendible tether connectable to an edge of a display panel at a first end and to a shutter door at a second end.

Embodiments of the twelfth aspect of the invention may comprise parts corresponding to the preferred or optional features of any other aspect of the invention or vice versa.

According to a thirteenth aspect of the invention, there is provided a method of determining the position of a display panel (or a vehicle bearing a display panel), the method comprising:
disposing a beacon on a vehicle;
applying the display panel to the vehicle;
arranging for the beacon to broadcast a message;
receiving the message at a consumer device; and
determining the position of the consumer device.

The position of the display panel (or the vehicle bearing the display panel) is taken to be the position of the consumer device when the message was received. Most preferably the position of the consumer device (or each consumer device as the case may be) is determined responsive to receiving the message.

Most preferably the consumer device (or consumer devices) communicates the position to a remote server which may aggregate the position received from a plurality of consumer devices to track the position of the display panel (or the vehicle bearing the display panel).

Optionally, the method comprises:
receiving the message at a plurality of consumer devices; and
determining the position of each consumer device when the message is received (most preferably responsive to receiving the message);
whereby the position of the display panel (or the vehicle bearing the display panel) is determined as a function of time.

If the message is received at different times by different consumer devices in different locations this information can be used to work out where the display panel (or the vehicle bearing the display panel) was at a particular time, or likewise when it was in a particular place, in a manner effectively verified by third parties.

Preferably, the beacon is disposed on the vehicle such that it is located behind the display panel when it is applied to the vehicle.

Preferably, the message comprises a URL which directs the consumer device to a server which receives the position of the consumer device.

Optionally, the method comprises correlating the position of the display panel with one or more databases to predict the extent to which the display panel has been exposed to the public.

Preferably, the position of the display panel is correlated with one or more databases to determine how many people can be expected to have seen the vehicle.

Optionally, the position of the display panel is correlated with one or more databases in real-time.

Optionally, the message relates to subject matter presented on the display panel applied to the vehicle.

Alternatively, or additionally, the message relates to or is dependent upon the position of the vehicle.

Preferably, applying the display panel to the vehicle comprises:
providing at least one reclosable fastening strip substantially around the perimeter of the display panel;
applying at least one reclosable fastening strip to the vehicle in a shape substantially corresponding to the display panel; and
pressing the respective reclosable fastenings together to removeably attach the display panel to the vehicle.

Preferably, applying the reclosable fastening strips comprises provided breaks or gaps to form outlets or vents to allow water or air to escape from behind the display panel.

The display panel may be applied to a window recess panel, for example on a van, and as such the display panel may be shaped to correspond with or to fit inside the window recess panel, and the reclosable fastening strip may be applied to or around the window recess panel.

Optionally, applying the display panel to the vehicle comprises applying at least one horizontal rail to the vehicle and receiving a corresponding at least one horizontal edge of the display panel in the at least one rail.

Alternatively, or additionally, applying the display panel to the vehicle comprises:
attaching a first end of the display panel to a first end of a shutter door;
attaching a tether to a second end of a shutter door; and
attaching a second end of the display panel to the tether;
wherein the tether is extendible to prevent stretching of the display panel as the shutter door is opened or closed.

Embodiments of the thirteenth (and fourteenth) aspect of the invention may comprise features corresponding to the preferred or optional features of any other aspect of the invention or vice versa. For example, the first, second, seventh to ninth, eleventh and twelfth aspects of the invention provide display panel attachment arrangements, associated methods and displays and a kit of parts, and embodiments of the thirteenth (and fourteenth) aspect of the invention may employ preferred and optional features of any of those aspects when applying the display panel to the vehicle. Likewise, the third and fourth aspects of the invention provides a display panel attachment which comprises a beacon configured to transmit or broadcast messages and an associated method, and embodiments of the thirteenth (and fourteenth) aspect of the invention may employ preferred and optional features of any of those aspects when broadcasting a message. The fifth aspect of the invention provides a method of determining the extent to which a display panel has been exposed to the public, and embodiments of the thirteenth (and fourteenth) aspect of the invention may employ preferred and optional features of the fifth aspect in this context.

In accordance with a fourteenth aspect of the invention there may therefore be provided a display panel attachment arrangement for applying a display panel to a vehicle in accordance with the thirteenth aspect, wherein the display panel attachment arrangement comprises at least one reclosable fastening to receive a corresponding at least one reclosable fastening of the display panel, the at least one reclosable fastening arranged on the vehicle to define a shape corresponding to the shape of the display panel.

At least one rail may be arranged along a top edge of the display panel attachment arrangement to receive a corresponding top edge of the display panel. The at least one rail may comprise a channel configured to receive a keder strip disposed along an edge of the display panel and a flange for attachment to the vehicle configured for location behind the display panel when in use.

The display panel attachment may comprise at least one tether, the tether connectable at a first end to an edge of the display panel, attachable at a second end to a shutter door, and extendible to prevent stretching of the display panel as the shutter door is opened or closed.

The display panel attachment arrangement preferably comprises a beacon arranged on or within the display panel attachment arrangement and configured to transmit one or more messages to one or more electronic devices in the vicinity of the vehicle.

The display panel attachment arrangement preferably comprises a beacon, wherein the beacon is integral to the display panel attachment arrangement. The beacon may be covered when the display panel is in place, and the display panel may assist in retaining the beacon on the vehicle.

There may also be provided a vehicle comprising the display panel attachment arrangement, and/or a kit of parts which, when assembled and applied to a vehicle, forms the display panel attachment. The sixth aspect of the invention relates to a vehicle and embodiments of the thirteenth and fourteenth aspects of the invention may employ preferred and optional features of the sixth aspect in this context.

According to a yet further aspect of the invention, there is provided a method of determining the position of a display panel, a display panel attachment arrangement to attach a display panel to a vehicle, apparatuses and methods of attaching a display panel to a vehicle, apparatuses and methods of transmitting or broadcasting one or more messages to one or more electronic devices in the vicinity of a vehicle, apparatuses and methods of determining the extent to which a display panel has been exposed to the public, a vehicle, a display panel attachment device, a display panel assembly, a display panel, a shutter door display, a truck, a kit of parts and/or a method for assembling any of the preceding, substantially as herein described with reference to the appended drawings.

### BRIEF DESCRIPTION OF THE DRAWING

There will now be described, by way of example only, various embodiments of aspects of the invention with reference to the drawings (like reference numerals being used to denote like features), of which:

FIGS. 1A and 1B are schematic representations of display panel attachment arrangements embodying at least one aspect of the invention;

FIG. 2 is a schematic representation of an alternative display panel attachment arrangement;

FIG. 3 is a schematic representation of a double-decker bus with a display panel attached thereto;

FIG. 4 is a schematic representation of an alternative display panel attachment arrangement;

FIG. 5 is a schematic representation of another alternative display panel attachment arrangement;

FIG. 6 is a schematic representation of a further alternative display panel attachment arrangement;

FIG. 7 is a schematic representation of yet another alternative display panel attachment arrangement;

FIG. 8 illustrates in schematic form a vehicle or advert tracking system embodying at least one aspect of the invention;

FIG. 9 illustrates in schematic form a vehicle or advert tracking system;

FIG. 10 is a schematic representation of a shutter door being prepared for installation of a display panel in accordance with at least one aspect of the invention;

FIG. 11 is a schematic representation of a display panel attachment device in accordance with at least one aspect of the invention;

FIG. 12 is a schematic representation of a shutter door and a display panel mounted on the shutter door in accordance with at least one aspect of the invention; and

FIG. 13 is a schematic representation of a connection arrangement between a display panel attachment device and a display panel in accordance with at least one aspect of the invention.

### DETAILED DESCRIPTION OF THE PREFERRED EMBODIMENTS

In the context of the present application, display panels shall be understood to include not only non-permeable or substantially non-permeable flexible sheets (such as continuous PVC sheets) but also permeable sheets such as mesh sheets (which might also comprise PVC), or plastic or cloth sheets made from woven natural or synthetic fibers, which allow air flow through the panel. It is preferred that after use, and in particular when the display panels are replaced with new display panels, the materials be recycled, for example as traffic cones or items of street furniture such as bollards and barriers.

### Display Panel Attachment Arrangement

Doing away with the need for obtrusive and expensive frames and reducing the requirement for specialist tools, the Applicant has developed an alternative display panel attachment arrangement that involves applying a rectangular frame (the frame) comprising reclosable fastening strips (which may be female or male, or neuter/dual) upon a vehicle substrate. Subsequently, a pre-printed vinyl banner (the display panel) is fitted with corresponding (male or female, or neuter/dual) reclosable fastening strips around the perimeter of the banner on the rear surface. The corresponding strips of the frame and the display panel are then pressed together to provide a robust attachment of the display panel to the vehicle, which is easily removed when desired, without the need to install rails or other expensive or complicated hardware. A non-limiting example of a suitable reclosable fastening strip is 3M™ Dual Lock™, although alternatives such as hook and loop fastenings (e.g. 3M™ Scotchmate™) or similar (e.g. Paiho® PaiGrip™) may be used.

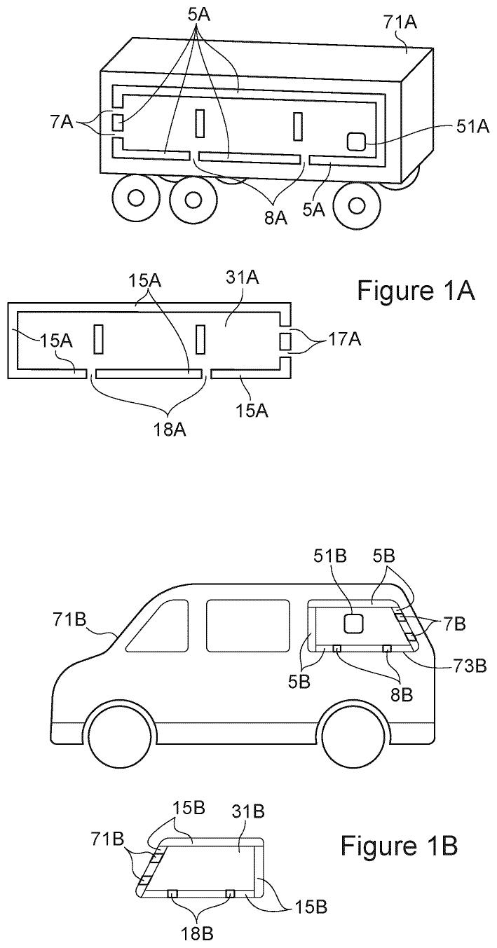

FIG. 1A illustrates an attachment arrangement 1A in accordance with an embodiment of the invention in which strips of reclosable fastenings 5A has been applied to a truck trailer 71A in a rectangular shape or outline. In this embodiment the shape or outline occupies the majority of the side of the truck trailer 71A but it might equally occupy the entire surface or a smaller portion of the surface, and indeed take any desired shape (not necessarily rectangular). The rear surface of a corresponding display panel 31A is also shown, which comprises reclosable fastening strips 15A which are attached to the display panel 31A in a corresponding pattern (in this case also rectangular).

The reclosable fastening strips 5A, 15A may be self adhesive or may be attached to the truck trailer 71A and/or the display panel 31A using glue, ultrasonic bonding, stapling, stitching or any other suitable means. Optionally, to aid in retaining the display panel 31A once applied, the perimeter of the display panel 31A might be sealed with tape or similar, corner protection might be applied to prevent unwanted peeling, or other discrete and more permanent attachments might be provided at the corners or at specific/predetermined locations around the perimeter of the display panel. The Applicant has found that such secondary attachments can be optional and primarily serve to provide comfort; other certain features described below aid in retention of the display panel in use.

Reference numerals 7A and 8A indicate optional outlets or vents which may be provided in the arrangement 1A by providing breaks or gaps in the frame (and on the corresponding display panel 31A) formed by the reclosable fastenings 5A. The rear outlets or vents 7A provide a means for air (primarily) to escape from behind the display panel 31A when in place, particularly when the vehicle is in motion, and the lower outlets or vents 8A provide a means for water to drain from behind the display panel 31A when in place. This can reduce the risk of the display panel 31A being loosened or removed when in use.

The Applicant has discovered that in use any air (or water) that is trapped behind the display panel 31A during the application process (or subsequently) is forced out, through the vents 7A and 8A, as the movement of the vehicle through the air results in a squeegee effect which progressively presses the display panel against the vehicle from the front to the back (relative to the direction of travel). As well as forcing (or squeezing) the air and/or water out from behind the display panel it tends to cause the display panel to stick to the side of the vehicle such that it is even more securely held in place by vacuum (or at least relative low pressure) behind the display panel. A further benefit is that the system never needs to be tensioned as the above-described process automatically tensions the display panel.

Of course the invention is not intended to be limited to truck trailers and display panels may be mounted on any external surface of any vehicles, as exemplified below, and it is also envisaged that the attachment arrangement may be adapted (again, examples follow) to suit particular applications or use cases.

In one particular alternative, the display panel is mounted inside a window recess panel of a van 71B as shown in FIG. 1B.

In this example, strips of reclosable fastenings 5B have been applied to a van 71B around the perimeter of a window recess panel 73B and thereby form a frame of corresponding shape (and size). The rear surface of a corresponding display panel 31B is also shown, which comprises reclosable fastening strips 15B which are attached to the display panel 31B around its perimeter. The shape of the display panel 31B matches the shape of the window recess panel 73B. Of course the shape can be any shape that would fit within the window recess panel 73B but it is more appealing if the shape is made to match.

This particular embodiment addresses various problems with vinyl graphics which are typically used to apply graphics to vans, for example letter ghosting or adhesive residue that can be left behind after removal. In addition to being unattractive, it makes changing vehicle graphics difficult and can incur penalties if the vehicle is leased. In contrast the inventive approach allows window recess panel graphics to be installed, changed and removed more quickly than using vinyl graphics (sometimes referred to as wraps). In fact, the inventive approach can even be applied over vinyl graphics or wraps, by applying the reclosable fastening strips directly to the vinyl surface (although it is preferred that they be applied directly to the van's painted surface). In this way a van might carry an overall design consistent from one to the next, with individual vans carrying different and changeable messages or advertisements as required. The display panel might for example bear region- or area-specific messages while the vans bear consistent livery.

As above, the reclosable fastening strips 5B, 15B may be self adhesive or may be attached to the van 71B and/or the display panel 31B using glue, ultrasonic bonding, stapling, stitching or any other suitable means. Likewise, to aid in retaining the display panel 31B once applied, the perimeter of the display panel 31B might be sealed with tape or similar, corner protection might be applied to prevent unwanted peeling, or other discrete and more permanent attachments might be provided at the corners or at specific/predetermined locations around the perimeter of the display panel.

Similarly, reference numerals 7B and 8B indicate outlets or vents which are provided in the arrangement 1B by providing breaks or gaps in the frame (and on the corresponding display panel 31B) formed by the reclosable fastenings 5B. In the same way, the outlets or vents 7B, 8B would provide a means for air and/or water to escape or drain from behind the display panel 31B when in place and particularly when the van 71B is in motion. This again reduces the risk of the display panel 31B being loosened or removed when in use, and indeed acts to positively cause the display panel 31B to stick to the surface of the vehicle. While it would be impractical on a large scale (such as an articulated lorry) it is foreseen that air and/or water could be manually expelled from behind the display panel 31B using a squeegee or similar to move air and/or water towards and out of the vents so as to improve retention in use without making it more difficult to remove at a later stage (as would be the case with adhesive). This approach might also be taken if the panel is attached to a window panel on the rear door where movement of the vehicle might not have the same effect.

In practice, it will be understood that more than one display panel can be provided if, as is typical, the van 71B comprises multiple window recess panels. If, for example, the van 71B has a sliding door which effectively splits a window recess panel, the display panel can likewise be split such that one half of the display panel 31B is on the sliding door and the other half of the display panel 31B is on the stationary part. Each part of the display may be provided with vents as described above.

Reference numerals 51A,51B indicates a beacon which can be disposed on the truck trailer 71A or the van 71B prior to application of the display panel 31A,31B such that the display panel 31A,31B obscures the beacon 51A,51B as well as securing it in place. It is shown in FIG. 1A as being located towards the front of the truck trailer 71A so as to be proximate a truck cab (not shown) but it can be positioned anywhere within the outline of the display panel attachment; in FIG. 1B the beacon 51B is located centrally where it is least likely to interfere with the reclosable fastenings. As per other embodiments the beacon can even be disposed in-line with the reclosable fastening tape; the main consideration is that the display panel assists in securing the beacon which is associated with it (in one way or another).

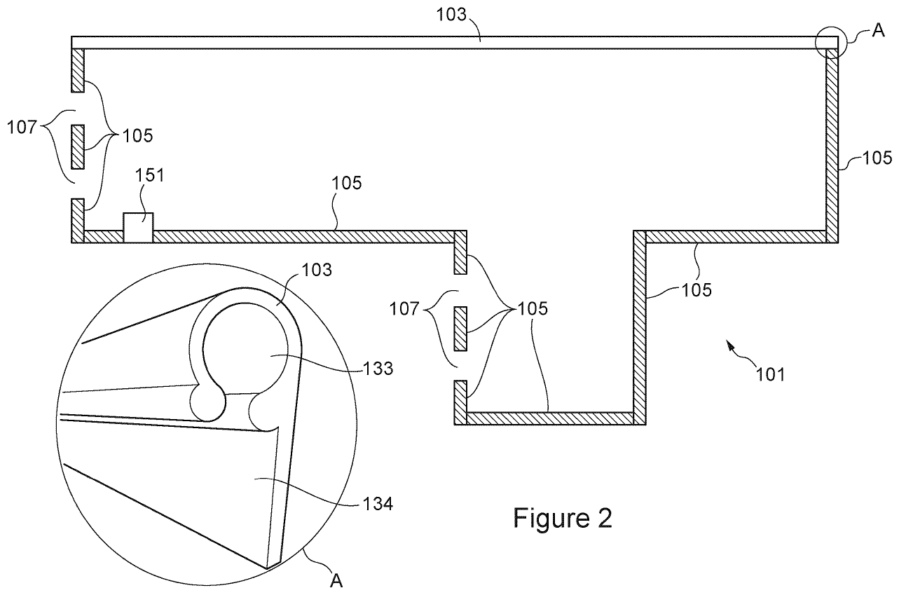

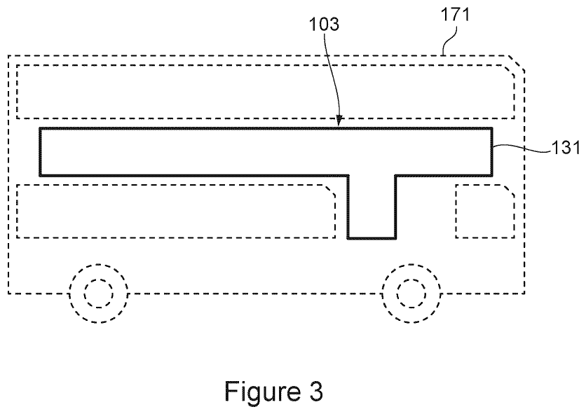

An alternative embodiment of the present invention is illustrated in FIG. 2 which also overcomes a number of disadvantages of the prior art and provides a number of additional features and advantages. This particular display panel attachment arrangement 101 relates to what is known in the art as a T-Side advertisement, commonly seen on the driver-side of double decker buses. To aid in understanding, FIG. 3 illustrates schematically how such a T-Side advertisement applied to a double decker bus 171 in accordance with the invention might appear to a user; importantly most of the attachment arrangement (and the beacon 151) is not visible once the display panel 131 has been applied.

The display panel attachment arrangement 101 (hereafter “attachment arrangement”) comprises a rail 103 which extends the full length of the attachment arrangement 101. This rail 103 receives and retains the top edge of a display panel 131 by means of a slot or channel 133 in the rail 103 which accommodates a corresponding keder strip formed along the top edge of the display panel (in place of the uppermost horizontal strip or strips of reclosable fastenings as shown in FIG. 1 and discussed above). This provides a reliable and repeatable means of locating and fixing the display panel to a vehicle, particularly when the display panel is large and/or when it is being installed by one person.

Although any rail and attachment may be employed, a “walking stick” type rail (see FIG. 2 inset A) is preferred as it minimises the amount of rail which is visible when the display panel is in place, while permitting a sizable flange 134 (which would be hidden behind the display panel in use) for secure attachment to the vehicle and reliable retention of a keder strip in the channel 133. In this way, the attachment of display panels to vehicles using reclosable fastenings is made even more secure than previously possible, without compromising (a) the ease with which such display panels can be applied and (b) the visual appeal of a frameless display panel.

The rail 103 can be attached to the vehicle using any appropriate temporary or permanent means, including adhesives or ultrasonic welding, however in this embodiment the rail 103, and in particular the flange 134 of the rail 103, is riveted onto the surface of the vehicle. In embodiments the flange can alternatively be attached using reclosable fastenings, for example to allow switching between display panels with and without keder strips.

The rest of the attachment arrangement 101 is provided by strips of reclosable fastenings 105 disposed on the surface of the vehicle in a shape corresponding to the outline of the display panel 131 which is to be attached thereto (so, for example, in a truck trailer application the shape would likely be rectangular as per FIG. 1). Corresponding strips of reclosable fastenings are to be located on the rear face of the display panel 131, around the perimeter and preferably close to the edge of the display panel 131 to avoid having loose material at the edges of the display panel 131 when attached to a vehicle that might cause unwanted detachment in windy conditions and/or when the vehicle is in motion.

Provided on the rear-most (relative to the front of the vehicle) vertical strips of the attachment arrangement 101 are, as in other embodiments, outlets 107 which enable fluid (e.g. air or water) which might be behind the display panel (when attached) to escape and thus prevent undesirable trapping of fluid behind the display panel, similar to the embodiment shown in FIGS. 1A and 1B. Although not shown here, outlets may instead, or additionally, be located on the lower-most (relative to the top of the vehicle) horizontal strips of the attachment arrangement 101 for the same reason. In motion, there may be advantages to having the outlets rear-most and when stationary there may be advantages to having the outlets lower-most. Of course outlets could be provided anywhere around the attachment arrangement 101.

Note, as mentioned at the beginning of the detailed description, the display panel may be permeable, e.g. comprising a PVC mesh or woven natural or synthetic fibers. As these tend to allow air flow through the panel there may be no need to provide vents although it may be preferred to provide them as a precaution. Likewise, if the display panel is sufficiently small, vents might be unnecessary regardless of whether the display panel is permeable or impermeable.

Reference numeral 151 indicates a beacon which can be disposed on the vehicle (optionally bus 171) prior to application of the display panel 131 such that the display panel 131 obscures the beacon 151 as well as helping to secure it in place, similarly to the beacon 51 described above. It is shown here as being located towards the rear of the vehicle and in-line with the reclosable fastening tape, though as mentioned above it may be located anywhere within the outline of the display panel attachment.

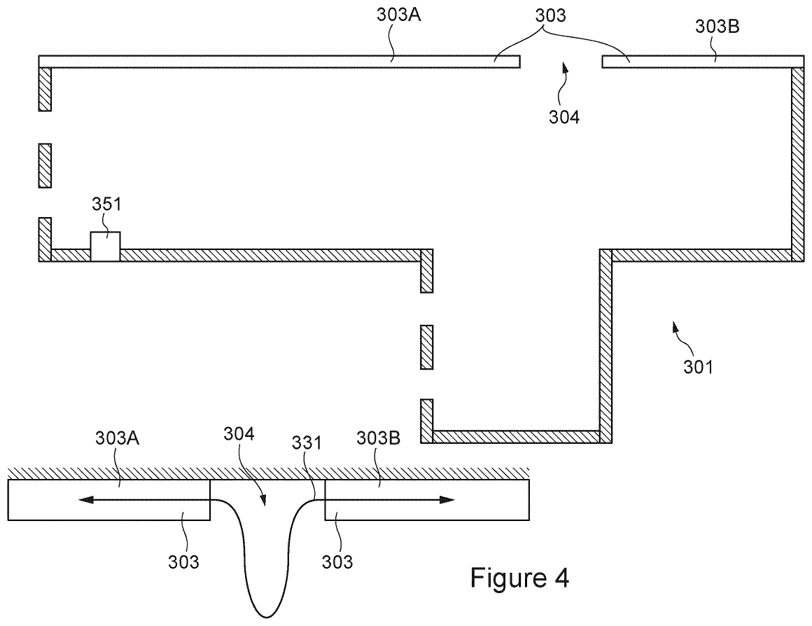

In the above embodiment, the rail 103 is described as extending the full length of the attachment arrangement. It is foreseen that to aid in the application of a display panel to a vehicle bearing the attachment arrangement the rail 103 might instead be provided with at least one gap, such as illustrated in the alternative embodiment shown in FIG. 4. In this embodiment, the gap 304 in the rail 303 enables a display panel 331 to be attached to the rail 303 from a more central position than the embodiment shown in FIG. 1, in which the display panel 131 must be fed onto and along the entire length of the rail 103 from either end. In the embodiment shown in FIG. 4, the left side of the display panel is fed onto the left rail portion 303A and the right side of the display panel is fed onto the right rail portion 303B from the gap 304. See FIG. 3 inset, which is a schematic top down view of the rail 303 in the vicinity of the gap 304 as a display panel 331 is being fed onto it.

It is foreseen that a portion of reclosable fastener might be located within the gap, with a reclosable fastener in a corresponding position on the display panel, to provide an additional or supplementary fastening once the display panel has been fed into the rail portions.

FIG. 4 (like the other Figures) is schematic and not drawn to scale; the features are exaggerated for the purposes of illustrating the invention in various and varied embodiments. In practice, the gap 304 may be relatively small—it only needs to be large enough to enable the display panel to be fed into the rail during attachment and, in theory, this could be quite a small gap. Indeed, absent (an optional) reclosable fastening the gap might function as an outlet such as described above, although it may be preferable to avoid ingress of water from the top of the display panel in which case a seal or cover may be provided to effectively close the gap once the display panel is in place.

Similarly, reference numeral 351 indicates a beacon which can be disposed on the vehicle prior to application of a display panel such that the display panel obscures the beacon 351 as well as helping to secure it in place. As with beacon 151 above, it is located towards the rear of the vehicle and in-line with the reclosable fastening tape; again, it may be located anywhere within the outline of the display panel attachment.

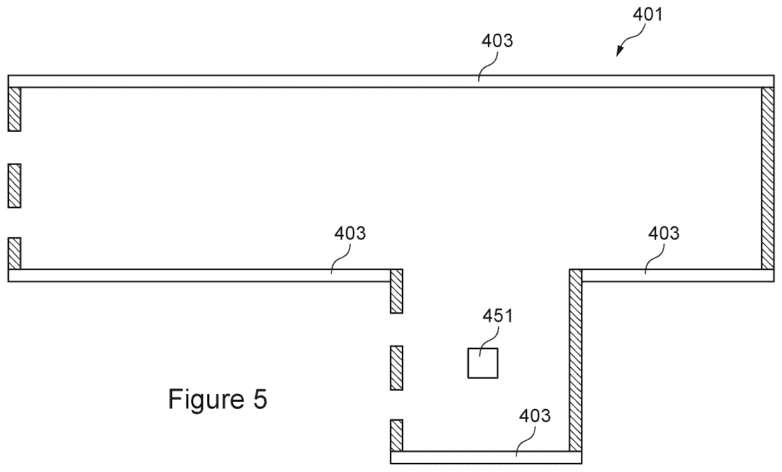

Note that it is envisaged that any portion of the attachment arrangement may comprise a rail. If multiple portions comprise rails the relevant portions should be parallel to as to enable a display panel with appropriate keder strips on corresponding edges to be fed onto the rails simultaneously. See for example FIG. 5 in which each of the horizontal portions of the attachment arrangement 401 comprise a rail 403 instead of strips of reclosable fastenings. Similarly, in another embodiment (not shown) each of the vertical portions of the attachment arrangement could comprise a rail instead of strips of reclosable fastenings. In summary; one, some or all horizontal portions could comprise rails, or one, some or all vertical portions could comprise rails. The remaining portions (horizontal and/or vertical) would comprise strips of reclosable fastenings.

Reference numeral 451 indicates a beacon which can be disposed on the vehicle prior to application of a display panel, again such that the display panel obscures the beacon 451 as well as helping to secure it in place, similarly to the beacons 51, 151 and 351 described above. It is shown here as being located inside the outline of the display panel attachment, spaced from the reclosable fastening tape, though as mentioned above it may be located anywhere within the outline of the display panel attachment including in-line with the reclosable fastening tape.

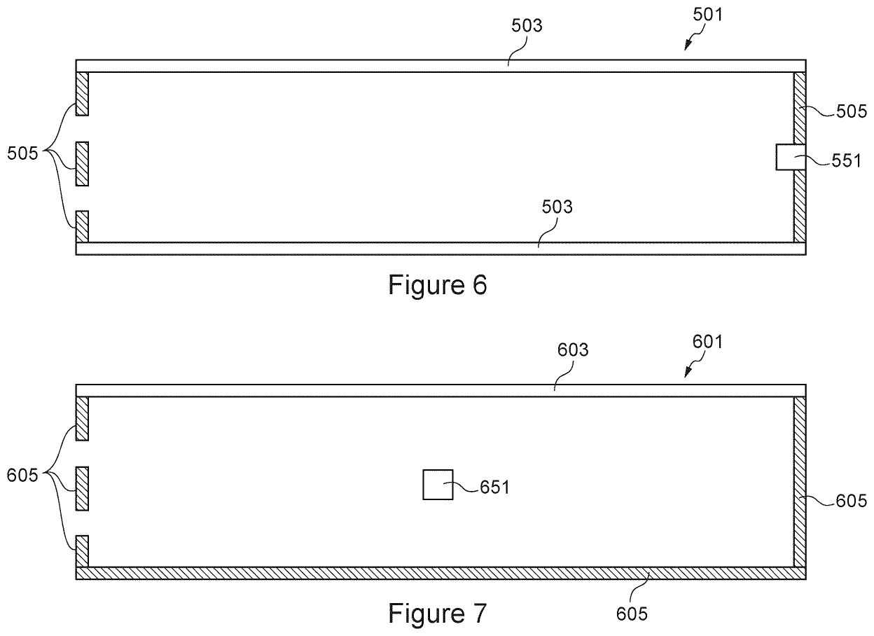

It is also envisaged that the attachment concept described above need not be limited to T-Side-type display panel arrangements. FIGS. 6 and 7 illustrate rectangular display panel attachment arrangements 501,601. In FIG. 6, horizontal rails 503 are provided along the top and bottom of the attachment arrangement 501, with the vertical portions comprising strips of reclosable fastenings 505, and in FIG. 7, only the upper horizontal portion of the attachment arrangement 601 comprises a rail 603—the lower horizontal portion comprises a strip of reclosable fastenings 605. In practice, any shape of display panel can be accommodated.

Reference numerals 551 and 651 indicate beacons which can be disposed on the vehicle prior to application of a display panel such that the display panel obscures the beacon 551 or 651 as well as helping to secure it in place, similarly to the beacons 51, 151, 351 and 451 described above. It is shown in FIG. 6 as being located towards the front of the vehicle and in-line with the front-most vertical portion of reclosable fastening tape, and in FIG. 7 as being located substantially centrally and within the outline of the display panel attachment, though as mentioned above beacons may be located anywhere within the outline of the display panel attachment.

### Beacon and Messaging

In the description of the embodiments above, it is explained that there is also provided a beacon 51,151,351, 551 and 651 as part of the display panel attachment arrangement. The beacon is shown as being integral to the attachment arrangement, in some embodiments by proximity to the reclosable fastenings and others by simply being located within the footprint such that it may be obscured and retained by the attached display panel. In some embodiments the beacon 151,351 is located on one of the horizontal portions or strips of reclosable fastenings, in one example the beacon 551 is located on one of the vertical portions or strips of reclosable fastenings, and in other embodiments the beacon 51,451,651 is spaced from the reclosable fastenings but still within the extent of the display panel. In practice, if outlets are provided in the attachment arrangement the beacon may be located in one of the outlets.

(For the avoidance of doubt, the beacon is not an essential component of the above-described attachment arrangement—and vice versa—although it is clearly complementary and may indeed be present in embodiments of the attachment arrangement).

The beacon, which in this embodiment is a Bluetooth™ low energy beacon but may in practice rely on any appropriate broadcast or push-messaging technology such as Apple's iBeacon™ or Google's Eddystone, is employed to transmit or broadcast messages and/or other data to nearby portable electronic devices. Note that the terms transmit and broadcast can be used interchangeably in the context of the present invention.

The messages transmitted or broadcasted by the beacon may typically be related to the subject matter presented on the display panel (although this is not essential). For example, if the display panel was mounted on a refuse collection truck and the message on the display panel related to a change to the refuse collection schedule, the beacon might push messages to nearby portable electronic devices (e.g. mobile phones) to remind people in the vicinity of the vehicle to put out their bins for collection on the correct day. If the display panel was mounted on a bus and was advertising a movie or theatre show, the beacon might push ticket offers or links to trailers or reviews to nearby portable electronic devices. At its very simplest implementation, the beacon might simply push a message to nearby electronic devices that the user should “look up”.

Alternatively, or additionally, the messages transmitted or broadcasted by the beacon may be dependent on or related to the position of the vehicle bearing the display panel (although the display panel is not essential in such an arrangement). For example, if the beacon was mounted on a rickshaw or the like which is being moved around pedestrianised or urban areas, the beacon might push messages to nearby portable electronic devices to inform people in the vicinity of the vehicle of offers or promotions in nearby shops. This may enable shops and other businesses to benefit from the advantages of beacon based messaging, perhaps on an ad-hoc or subscription basis, without having to invest in their own systems.

Integrating the beacon with the display panel attachment arrangement described above has considerable advantages, not least because it solves the technical problem of ensuring that important communications are conveyed to members of the public or potential customers. It can also ensure that messages are only sent to people who can actually see the display panel to which the message relates.

It will also be understood that, as shown in FIGS. 1, 5 and 7, the beacon need not be integrated with the attachment arrangement itself, but is it strongly preferred that the beacon 451, 651 be at least located within the boundary of the display panel area defined by the attachment arrangement (i.e. within an area bounded by the rail(s) and reclosable fastenings). Accordingly, when the display panel is in place, the beacon is covered and the display panel itself assists in keeping the beacon in place.

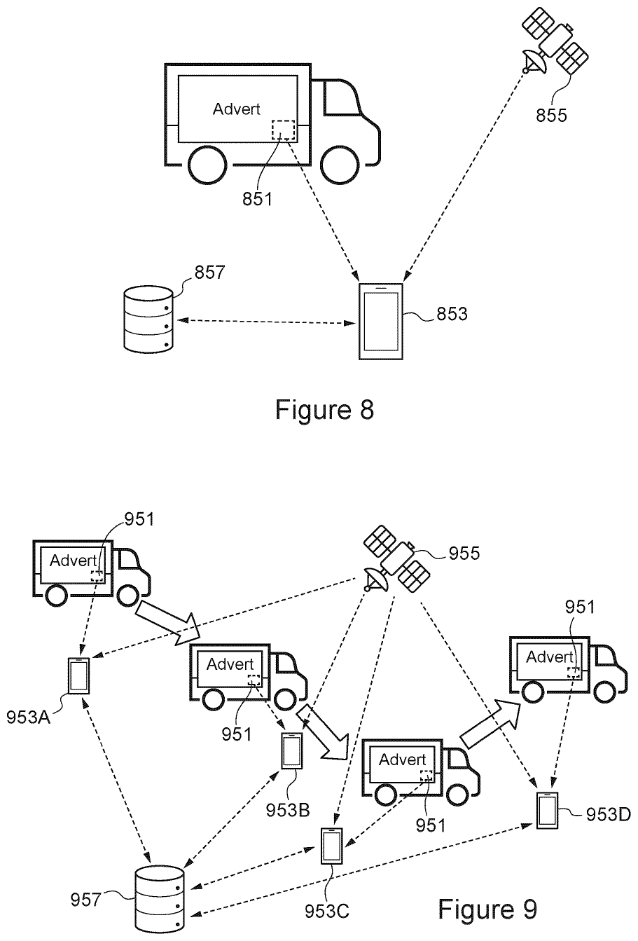

A use case will now be described which makes use of the beacon and which forms embodiments (and variants) of the invention. As discussed further below, it is anticipated that a consumer will have a client app or similar software installed on a smart device and that the app will be configured to receive messages from nearby beacons and present or otherwise communicate to the consumer. Reference is made to the simplified arrangement shown in FIG. 8, which illustrates a consumer device 853 running a client app, a vehicle (in this case a truck) carrying a display panel of the kind described herein (or otherwise) and a beacon 851 located behind the display panel (and associated with the display panel). A server 857 (or similar hardware or software) stores a message associated with a URL that will be broadcast by the beacon 851 to nearby consumer devices which are running the aforementioned client app. There is also shown a satellite 855 being a generalised depiction of a positioning system/service such as GPS which permits the consumer device 853 and hence the app to know its position (this should include any alternative such as cell tower information).

In a first example, a landing page is created on the server 857 and the beacon 851 configured to point to a corresponding landing page URL. The client app is configured to receive beacon notifications and when the vehicle is sufficiently close (i.e. within the beacon's broadcast range) a notification is received by the client app and the consumer navigates to the message (which may be a marketing message but the invention is not so limited as described elsewhere). The server 857 collects analytics/data as part of this process (a particular benefit of which is described further below).

It can be arranged that only consumers who are interested receive the message, having self-selected for example by installing the client app. Furthermore, by pointing to a landing page URL the client is able to adapt or update the message (which, again, may be a marketing message), and this would have the effect of being able to dynamically change the message based on any desirable criteria. It may be the case that the client elects to have a time-dependent message (for example if an offer has a limited timescale or is limited by numbers of exposures) or a location-dependent message which can utilise position data from the positioning system/service 855. The message can also be client, consumer and/or device specific, particularly if the client app is configured to share relevant metadata with the server 857.

The landing page may be configured to collect analytic data by embedding a tag or tracking code which tracks activity such as events, clicks, page scrolls, geolocation, browser and device information, session duration and any other metric that might be useful to the client, including conversions (e.g. sales, offer acceptances, file downloads or click-throughs). Notably, geolocation (or position) of the consumer device when the message is received also provides an indication of the vehicle (or the display panel) position which can be communicated to the server providing a means of determining the position of the vehicle (or the display panel) as discussed in more detail below.

In summary, a way of determining the position of a display panel, or a vehicle bearing the display panel, is enabled without the need for a dedicated location tracker. This has cost implications as well as reducing power consumption meaning the beacons can operate much longer than otherwise. If the message is received at different times by different consumer devices in different locations this information can be used to work out where the display panel (or the vehicle bearing the display panel) was at a particular time, or likewise when it was in a particular place, in a manner effectively verified by third parties.

### Vehicle Tracking and Analysis

The beacon discussed above, or in the absence of (or indeed in addition to) such a beacon a separate tracking unit (shown schematically by reference numeral 171 in FIG. 2) provided on or in the vehicle (e.g. 151), may be used to monitor, record and (optionally) transmit the position of the vehicle. Tracking the position of the vehicle in the context of the present application provides for greater functionality than might be apparent without the benefit of hindsight.

(For the avoidance of doubt, vehicle tracking and analysis is not an essential component of the above-described attachment arrangement or of the beacon and messaging system—and vice versa—although it is clearly complementary to each and both of these aspects and may indeed be present in embodiments of the attachment arrangement and/or the beacon and messaging system).

By way of example, it will be understood that display panels for attachment to vehicles in accordance with the foregoing will find particular utility in advertising or marketing campaigns. To date it has not been possible to reliably determine or predict how many people have seen a particular advert. However, allied with the applicant's proprietary Roadvert® software—which enables prediction of audiences based on reliable data sourced from, for example, official Government statistics—aggregated positional data can be correlated with data from the Roadvert® software to determine (a) how many people can be expected to have seen the vehicle and hence a display panel on the vehicle (i.e. the size of the audience) and (b) the geographical make-up of that audience. Audience prediction be broken down to National, Regional, County and even Local Authority levels if required. An ancillary benefit is that it enables a value to be attributed to the advertising space on any particular vehicle based on its movements.

The impact of the inventive concept becomes significant when applied across a fleet of several vehicles; the actual exposure of a particular advertisement or marketing campaign can be reliably determined (or at least predicted) and monitored based on the aggregated positional data across the fleet and its correlation with Roadvert® data. This can be done, for example, on a real-time basis and/or as and when vehicles return to a predetermined location or base.

When combined with the beacon aspect described above, this data can be supplemented with information on actual interactions with portable electronic devices which provides a measure of (a) audience proximity and (b) confirmed exposures (e.g. number of successful push messages). There is also described below a particular application or use case enabled by embodiments of the invention which provides an alternative position tracking functionality without requiring GPS (or similar) enabled beacons. Position information obtained in this way can also be used to determine or at least predict the exposure of a display panel to the public.

### Additional Functionality and Applications

It will be understood that the vehicle tracking aspect of the invention and the beacon and messaging aspect of the invention may interact or otherwise cooperate to provide additional or enhanced functionality. For example, knowledge of the vehicle's location (from the tracking aspect) will enable the transmission of even more location-aware or location-relevant messages (from the beacon aspect).

As the beacon might also be used to identify how many devices in the vicinity of the vehicle received a broadcast message, this may also be used to corroborate or at least supplement the exposure data determined or calculated from statistical data and positional data alone.

Importantly, it is also envisaged that display panel arrangements, beacons and/or vehicle tracking and analysis, may be applied to any kinds of vehicle—not just buses or heavy goods vehicles. The present invention in its varied and various embodiments may be applied to cars, vans, trucks, HGVs, trains, trams, refuse collection vehicles, smaller vehicles such as rickshaws, carts, or other movable or wheeled objects, and even static sites where appropriate. For example, while it does not make sense to deploy positional tracking on a static site, a static site could make use of the improved attachment arrangements described herein, and/or the beacon and messaging aspects.

In an implementation of the invention, a beacon such as the beacon(s) described above may be installed on a vehicle such as a truck bearing a display panel (which might comprise an advertisement and/or other graphic(s)). When the driver of the vehicle enters the vehicle he or she may dock their smartphone (or similarly/suitably enabled device) in the vehicle, whereupon an app (such as the Applicant's proprietary Roadvert® app) detects and/or otherwise communicates with the beacon on the truck. The beacon then provides information to the smartphone app regarding the content of the display panel. For example, the beacon might transmit a full colour copy of an advertisement on the display panel to the smartphone app.

The above-described audience predicting can be used to determine how many impressions the vehicle, and hence the display panel and associated advertisement and/or graphic, will make on its route. The smartphone app can alert a central platform or otherwise determine and communicate the actual number of impressions made.

Knowledge of the actual audience allows comparison with the predicted audience to ascertain media values. It also delivers the number of beacon “hits” and any associated conversion rates/ratios.

Other smartphones in the vicinity of the vehicle (and specifically within a predetermined range of the beacon) and which have (for example) the Applicant's proprietary Roadvert® app installed and/or a client app, are able to receive messages (for example coupons or contextually relevant messages) directly from the beacon. For example, if a pedestrian or driver has a cinema app on their smartphone and is exposed or otherwise in the vicinity of a vehicle bearing an advertisement for a new film release, the beacon might transmit a voucher for that film for use at the relevant cinema.

Use of a client or other specific app ensures that the transmitted message or coupon reaches an audience who is already willing to engage with the source of the message. As such smartphones may be in the possession of drivers in the vicinity of the vehicle (beacon) the corresponding notification may be silent.

This arrangement also provides a convenient means of tracking the position of the vehicle (or the display panel), which can be independent of a driver device and/or independent of GPS functionality in a beacon itself. Another use case will now be described which makes use of the beacon and which forms embodiments (and variants) of the invention. As discussed elsewhere herein, it is anticipated that consumers will have a client app or similar software installed on a smart device and that the app will be configured to receive messages from nearby beacons and present or otherwise communicate to the consumer.

Reference was made above to the simplified arrangement shown in FIG. 8, which illustrates a consumer device 853 running a client app, a vehicle (in this case a truck) carrying a display panel and a beacon 851, while a server 857 underpins the messaging functionality provided by the beacon 851 and position data is obtained via a positioning system 855.

FIG. 9 illustrates a particular variant of the arrangement shown in FIG. 8, in which a beacon 951 encounters several consumer devices 953A,953B,953C,953D as it drives around (indicated generally by arrows). Each consumer device 953A,953B,953C,953D is running the client app and receives messages from the beacon 951 as it passes nearby. When the consumer interacts with the message, which directs them to a landing page on the server 957, the client app not only displays (or otherwise communicates) the message to the user but it communicates certain data to the server 957 as noted above. Included in this data is position data, which may be acquired from the positioning system 855. It is therefore possible to determine the position of the beacon as a function of time, and hence track the vehicle and/or the display panel.

The benefit of this arrangement is that by collecting position data from one, but preferably several, consumer devices, there is direct evidence of (a) a (potential) exposure of the vehicle to an interested (and self-selected) consumer, (b) actual interaction of the consumer with the message, and (c) at least an indication, and perhaps a verification, of the position of the vehicle. This position data can be time-stamped at the server 957 and does away with the need for a GPS-enabled beacon and the position information can provide an input to the applicant's proprietary audience prediction analysis described above to give accurate estimates of exposure to any consumers (not just those who have the app and/or receive beacon notifications).

### Display Panel Attachment for Shutter Doors

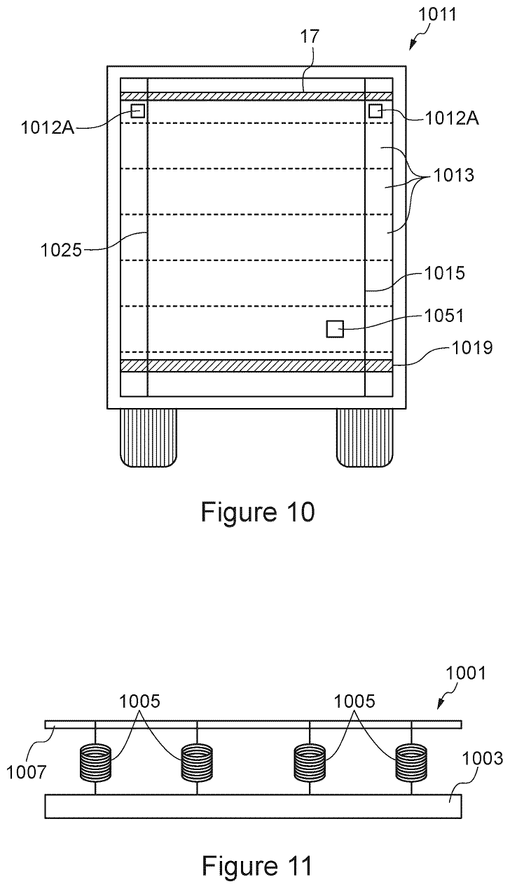

As discussed in the background to the invention above, a typical shutter door 1011 as illustrated in FIG. 10 comprises a number of horizontal slats 1013 which are interlocked, interlinked or otherwise hingedly joined to permit relative rotation between the slats as the shutter door 1011 is opened or closed. A guide rail 1015 for the slats 13 extends the length of the shutter door 1011.

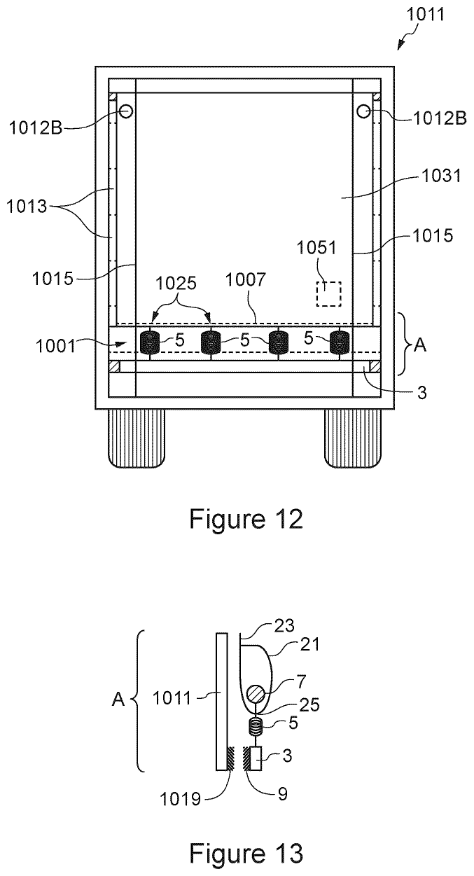

In preparation for the attachment of a display panel (not shown here—see FIG. 12) to the shutter door 1011, a first strip 1017 of Dual Lock™ fastening is applied proximal an upper edge of the shutter door 1011. A second strip 1019 of Dual Lock™ fastening is applied proximal a lower edge of the shutter door 1011. The display panel (not shown here—see FIG. 12) will be attached directly to the shutter door 1011 at the first strip 1017, and to a display panel attachment device (not shown here—see FIG. 14) attached or attachable to the second strip 1009.

FIG. 11 illustrates a display panel attachment device 1001 which comprises a flat bar 1003 which is attachable to the second strip 1019 of Dual Lock™ by a corresponding strip of Dual Lock™ fastening applied to the rear (not visible here—see FIG. 13). The flat bar 1003 has been pre-drilled to receive the ends of springs 1005 which extend between the flat bar 1003 and a rod 1007 by which the springs 1005 are connected to the display panel (as further described below with reference to FIG. 13).

When installed, as shown in FIG. 12, the display panel 1021 covers the slats 1013 of the shutter door 1011, affixed directly to the shutter door 1011 itself along a top edge of the display panel 1021 and to the display panel attachment device 1001 along a bottom edge of the display panel 1021. As described in the background to the invention, as the shutter door 1011 is opened the effective length of the shutter door 1011 increases. The presence of the springs 1005, which extend accordingly, prevent stretching of the display panel 1021 which would otherwise stretch or otherwise damage the display panel 1021. When the shutter door 1011 is closed again, the springs 1005 retract accordingly.

Note that it is advantageous and indeed preferred that the display panel attachment device 1001 is attached to the display panel 1021 and to the shutter door 1011 in such a way that the display panel 1021 is tensioned even when the shutter door is in the closed position. This may be achieved and varied in practice by making adjustments to the position at which the bar 1003 is connected to the shutter door-assisted by the use of reclosable fastenings.

FIG. 13 illustrates in greater detail the connection between the display panel attachment device 1001 and the display panel 1021 in a cross-sectional view of the area marked A in FIG. 12. The display panel 1021 has been looped back on itself and heat sealed to provide an enclosed channel along its lower edge which receives the rod 1007 of the display panel attachment device 1001. When making the attachment, the ends of the springs 1005 are inserted into the channel through a number of apertures 1025 (which may be pre-formed or pre-cut, or cut at the time of installation) along the lower edge of the display panel 1021. The ends of the springs 1005 are provided with loops through which the rod 1007 is threaded.

To retain the rod 1007 in the channel, end caps (not shown) larger than or commensurate with the size of the channel may be attached to the ends of the rod 1007—for which the ends of the rod may be threaded.

Alternatively, the ends of the springs could be provided with hooks and the attachment made in the same way or, instead, the rod inserted in the channel then the hooks attached to the rod through the apertures.

In any case, the rod 1007 operatively connects the springs 1005 to the display panel. At the other end of the springs 1005, by means of corresponding loops or hooks, they are connected to the bar 1003 which can be seen to have a strip 1009 of Dual Lock™ applied to the rear corresponding to the strip 1019 applied to the lower end of the shutter door 1011.

As an optional reinforcement, clips can be installed at strategic locations to strengthen the attachment of the display panel to the shutter door where a direct attachment is made. As shown in FIG. 10, clip bases 1012A can be affixed to the shutter door 1001 prior to installation of the display panel and, after installation of the display panel 1021 corresponding clip heads 1012B attached to the clip bases 1012A as shown in FIG. 12. The clip bases may comprise protrusions which are received in corresponding apertures in the clip heads in a secure manner. In this way, unwanted detachment of the display panel from the shutter door 1001 can be avoided.

In the foregoing description the display panel is fixedly attached to the top of the shutter door but it is foreseen that the extendible attachment may instead be provided at the top of the shutter door with the display panel fixedly attached to the bottom of the shutter door. Likewise, for increased flexibility, an extendible connection might be provided at both ends of the display panel by use of two display panel attachment devices according to the invention.

Furthermore, while a spring is described any form of extendible connection might be employed—for example another type of resilient connection could be provided by use of elasticated cord such as bungee rope. Alternatively, the extendible connection could be retractable; for example relatively inelastic wires or sheets of material connecting the display panel to a tensioned roller on which they are disposed. It is also foreseen that the display panel itself could be attached directly to the tensioned roller—the tensioned roller paying out and retracting a portion of the display panel corresponding to the increased effective length of the shutter door as it is opened.

Another unexpected benefit of the invention is that by enabling the attachment of single sheet display panels, shutter doors to which said display panels are attached are protected from the elements. It has come to the Applicant's attention that shutter doors may require replacement as often as once per year due to corrosion and damage (including damage caused by removal of adhesive decals), and it is foreseen that by covering the joints between adjacent slats and negating the need to remove adhesive panels which don't even cover the joints, the lifespans of shutter doors in industry can be radically improved.

Finally, reference numeral 1051 indicates a beacon which can be disposed on the vehicle prior to application of the display panel 1031, again and similarly to previous embodiments, such that the display panel 1031 obscures the beacon 1051 and possibly helping to secure it in place, similarly to the beacons 51, 151, 351, 451, 551 and 651 described above. It is shown here as being located inside the outline of the display panel, spaced from the edges, though as mentioned above it may be located anywhere within the outline of the display panel attachment including in-line with the reclosable fastening tape if desired. The beacon might alternatively be embedded or otherwise attached or form part of the display panel attachment device 1001.

Embodiments of the invention provide a display panel attachment arrangement having at least one rail to receive an edge of a display panel, and at least one reclosable fastening to receive a at least one reclosable fastening of the display panel, the at least one rail and the at least one reclosable fastening arranged on the vehicle to define a shape corresponding to the shape of the display panel. A corresponding method is provided for attaching a display panel to a vehicle. A beacon may be provided to transmit or broadcast messages to electronic devices in the vicinity of a vehicle on which it is located, and a corresponding method is also provided. The extent to which a display panel has been exposed to the public can be determined by tracking the position of a vehicle to which the display panel is attached to generate positional data, and correlating the positional data with one or more databases. Embodiments of the invention also provide means by which a display panel can be attached to a shutter door such that the display panel is not damaged when the shutter door is opened and closed. A display panel attachment device comprises at least one extendible tether which connects at least one end of the display panel to the shutter door.

The extendible tether compensates for the effective increase in length of the shutter door during opening and closing. Rather than allow the display panel to be stretched, the tether extends to increase the effective length of the display panel. There is also provided a method by which the position of a display panel or of a vehicle can be determined by broadcasting a message from a beacon associated with the display panel or vehicle, receiving the broadcast message at a consumer device, determining the position of the consumer device when the message is received, and taking that position to be the position of the display panel or vehicle. If this is done with multiple messages and/or multiple consumer devices the position of the display panel or vehicle can be tracked as a function of time.

As used herein, the terms back or rear, bottom, lower, below and the like are descriptive of a feature that is located towards a first end/side of an apparatus, system or component while the terms front. top, upper, above and the like are descriptive of a feature that is located towards a second, opposing end/side of the apparatus, system or component. For example, front may refer to the end of a vehicle towards the normal direction of travel in which case back or rear refers to the opposite end of the vehicle. It is also foreseen that a shutter door could operate in a sideways orientation and the above-described shutter door display panel attachment would function in a similar way.

Throughout the specification, unless the context demands otherwise, the terms “comprise” or “include”, or variations such as “comprises” or “comprising”, “includes” or “including” will be understood to imply the inclusion of a stated integer or group of integers, but not the exclusion of any other integer or group of integers.

The foregoing description of the invention has been presented for the purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention as defined by the appended claims. For example, various attachment arrangements have been described above and it will be understood that features shown in the context of one embodiment may readily be employed in other embodiments without difficulty. For example, the embodiments shown in and described with reference to FIGS. 1 and 10 to 13 might be modified to employ a keder strip along a top and/or any other edge; the embodiments shown in and described with reference to FIGS. 2 to 7 might be modified to provide reclosable fastenings around the entire perimeter instead of keder strips; and in any of the embodiments disclosed herein a beacon or beacons may be disposed anywhere within the area defined by the attachment arrangements.

What is claimed is:

1. A method of determining the position of a display panel or of a vehicle, the method comprising:
disposing a beacon on a vehicle;
applying the display panel to the vehicle;
arranging for the beacon to broadcast a message;
receiving the message at a consumer device; and
determining the position of the consumer device when the message is received;
wherein the position of the display panel or of the vehicle is taken to be the position of the consumer device when the message was received.

2. The method of claim 1, comprising;
receiving the message at a plurality of consumer devices at different times; and
determining the position of each consumer device when the message is received;
whereby the position of the display panel or of the vehicle is determined as a function of time.

3. The method of claim 1, wherein the position of the or each consumer device is determined responsive to receiving the message.

4. The method of claim 1, wherein the position of the or each consumer device is communicated to a remote server which aggregates the position received from the or each consumer device to track the position of the display panel or of the vehicle.

5. The method of claim 1, wherein the beacon is disposed on the vehicle such that it is located behind the display panel when it is applied to the vehicle.

6. The method of claim 1, wherein the message comprises a URL which directs the consumer device to a server which receives the position of the consumer device.

7. The method of claim 1 further comprising correlating the position of the display panel or of the vehicle with one or more databases to predict the extent to which the display panel has been exposed to the public.

8. The method of claim 7, wherein the position of the display panel is correlated with one or more databases to determine how many people can be expected to have seen the vehicle.

9. The method of claim 7, wherein the position of the display panel is correlated with one or more databases in real-time.

10. The method of claim 1, wherein the message relates to subject matter presented on the display panel applied to the vehicle.

11. The method of claim 1, wherein the message relates to or is dependent upon the position of the vehicle.

12. The method of claim 1, wherein applying the display panel to the vehicle comprises:
providing at least one reclosable fastening strip substantially around the perimeter of the display panel;
applying at least one reclosable fastening strip to the vehicle in a shape substantially corresponding to the display panel; and
pressing the respective reclosable fastenings together to removeably attach the display panel to the vehicle.

13. The method of claim 12, wherein applying the reclosable fastening strips comprises providing breaks or gaps to form outlets or vents to allow water or air to escape from behind the display panel.

14. The method of claim 12, wherein the display panel comprises the shape of a window recess panel of the vehicle and the at least one reclosable fastening strip is applied to or around the window recess panel of the vehicle.

15. The method of claim 1, wherein applying the display panel to the vehicle comprises applying at least one horizontal rail to the vehicle and receiving a corresponding at least one horizontal edge of the display panel in the at least one rail.

16. The method of claim 1, wherein applying the display panel to the vehicle comprises:
attaching a first end of the display panel to a first end of a shutter door;
attaching a tether to a second end of a shutter door; and
attaching a second end of the display panel to the tether;
wherein the tether is extendible to prevent stretching of the display panel as the shutter door is opened or closed.

17. A display panel attachment arrangement for applying a display panel to a vehicle in accordance with claim 1, the display panel attachment arrangement comprising at least one reclosable fastening to receive a corresponding at least one reclosable fastening of the display panel, the at least one reclosable fastening arranged on the vehicle to define a shape corresponding to the shape of the display panel.

18. The display panel attachment arrangement of claim 17, further comprising at least one rail arranged along a top edge of the display panel attachment arrangement to receive a corresponding top edge of the display panel, wherein the at least one rail comprises a channel configured to receive a keder strip disposed along an edge of the display panel and a flange for attachment to the vehicle configured for location behind the display panel when in use.

19. The display panel attachment arrangement of claim 17, wherein the at least one reclosable fastening is arranged on the vehicle with breaks or gaps to form outlets or vents to allow water or air to escape from behind the display panel.

20. The display panel attachment arrangement of claim 17, wherein the display panel attachment device comprises at least one tether, the tether connectable at a first end to an edge of the display panel, attachable at a second end to a shutter door, and extendible to prevent stretching of the display panel as the shutter door is opened or closed.
